(19) United States
(12) Patent Application Publication
(10) Pub. No.: US 2012/0086091 A1
(43) Pub. Date: Apr. 12, 2012

(54) BACKSIDE IMAGE SENSOR

(75) Inventor: Axel Crocherie, Grenoble (FR)

(73) Assignee: STMicroelectronics S.A., Montrouge (FR)

(21) Appl. No.: 13/237,765

(22) Filed: Sep. 20, 2011

(30) Foreign Application Priority Data
Oct. 8, 2010 (FR) 10/58194

(51) Int. Cl. H01L 27/146; H01L 31/0232

(52) U.S. Cl. 257/432; 257/E31.127; 257/E27.13

(57) ABSTRACT

A backside image sensor including an assembly of pixels, each pixel including, in a vertical stack, a photosensitive area and a filtering element topping the photosensitive area on the back surface side, wherein at least two adjacent filtering elements of adjacent pixels are separated by a vertical metal wall extending over at least eighty percent of the height of the filtering elements or over a greater height.

### CROSS REFERENCE TO RELATED APPLICATIONS

This application claims the priority benefit of French patent application number 10/58194, filed on Oct. 8, 2010, entitled “BACKSIDE IMAGE SENSOR,” which is hereby incorporated by reference to the maximum extent allowable by law.

### BACKGROUND OF THE INVENTION

1. Field of the Invention

The present invention relates to an image sensor. It more specifically aims at a back-illuminated color image sensor.

2. Discussion of the Related Art

FIG. 1 is a cross-section view schematically showing a portion of a backside color image sensor 1, formed inside and around a semiconductor substrate 3, for example, a silicon substrate.

Here and in the rest of the present description, the “front surface” of a semiconductor chip (for example, an image sensor) will be the chip surface on the side of which the various metallization levels for interconnecting the chip components are formed. The “back surface” is the chip surface opposite to the front surface.

Substrate 3 is a thin substrate (thinned down), for example, having a thickness ranging from 1 to 5 μm, covered with a stack 5 of metallic and insulating interconnection layers on its front surface side. Sensor 1 is formed of an array of pixels 7 formed inside and around substrate 3.

Each pixel 7 comprises an active photosensitive area 9 formed in substrate 3, generally corresponding to a photodiode capable of storing an amount of electric charges which depends on the received light intensity. Photosensitive area 9 is, for example, square- or rectangle-shaped in top view, and substantially extends across the entire thickness of substrate 3. The photosensitive areas 9 of neighboring pixels are separated by insulating regions 11, for example, trenches filled with silicon oxide extending vertically from the front surface to the back surface of substrate 3.

Conductive tracks 13 of interconnection stack 5, and conductive vias, not shown, enable addressing the pixels and to collect electric signals.

On the back side of the sensor, each pixel 7 further comprises a color filtering element 15, for example, an organic filter, arranged opposite to the portion of substrate 3 associated with the pixel. In practice, the filtering elements 15 of adjacent pixels are appended, the assembly of elements 15 of the sensor defining a filtering layer having a thickness approximately ranging from 0.5 to 1.5 μm, topping the back side of the substrate. The back side of the filtering layer is generally covered with a thin equalization layer 16, for example, an oxide or planarizing resin layer with a thickness approximately ranging from 100 to 300 nm, which defines a surface of exposure to light.

To concentrate the light intensity received at the pixel surface towards the associated photosensitive area 9, each pixel 7 further comprises a microlens 17, arranged on the back surface side of layer 16, opposite to filtering element 15 of the pixel.

As an example, to form a sensor of this type, it is started from a substrate 3 of standard thickness, for example, of a few hundreds of μm, in the upper portion of which photosensitive areas 9 and insulating regions 11 are formed. Interconnection stack 5 is then formed at the surface of substrate 3, and a support handle wafer is appended to the front surface of the interconnection stack. While the sensor is being held from the support handle wafer, substrate 3 is thinned from its back surface. After the thinning, filters 15, equalization layer 16, and microlenses 17 are formed on the back surface side of the substrate. It should be noted that such a sensor may also be similarly formed from a substrate of silicon-on-insulator type, comprising a thin semiconductor layer formed at the surface of an insulating support.

Backside image sensors generally have a better sensitivity than front-illuminated sensors, since light rays do not have to cross interconnection stack 5 to reach photosensitive regions 9.

However, a disadvantage of such sensors is that they are particularly prone to color mixing phenomena between neighboring color filters. In particular, a light ray may cross two adjacent filters 15 of different colors before reaching a photosensitive area 9. A light ray may also be essentially filtered by a filter 15 of a first color, and reach the photosensitive area 9 of a neighboring pixel, associated with another color. Such phenomena are currently called “optical crosstalk” and adversely affect the quality of the images acquired by the sensor. They especially occur when light rays reach filters 15 with poorly adapted angles of incidence, for example, in case of a poor alignment of microlenses 17, or in case of parasitic reflections in the sensor. Such phenomena are particularly strong in the peripheral regions of the sensor, in which the pixels are illuminated by light rays having relatively high angles of incidence, which may exceed 30°.

To limit crosstalk phenomena and improve the sensor sensitivity, it may be provided, for each pixel of the sensor other than the central pixel(s), to offset, in top view, filter 15 and microlens 17 with respect to photosensitive area 9, by a distance depending on the pixel position on the sensor. The offset introduced is selected according to the angle of incidence of the rays normally illuminating the pixel, to have these rays converge at best towards the photosensitive area. In practice, the more remote the pixel from the center of the sensor, the larger the offset.

However, the provision of such an offset makes the manufacturing of sensors relatively complex.

Further, there however remain non-negligible crosstalk phenomena between adjacent pixels.

### SUMMARY OF THE INVENTION

Thus, an embodiment provides a backside image sensor, which overcomes at least some of the disadvantages of existing solutions.

An embodiment decreases crosstalk phenomena between neighboring filters in a backside image sensor.

An embodiment provides a backside image sensor, which is easy to form as compared with existing solutions.

Thus, an embodiment provides a backside image sensor comprising an assembly of pixels, each pixel comprising, in a vertical stack, a photosensitive area and a filtering element topping the photosensitive area on the back surface side, wherein at least two adjacent filtering elements of adjacent pixels are separated by a vertical metal wall extending over at least eighty percent of the height of the filtering elements or over a greater height.

According to an embodiment, the sensor further comprises an equalization layer topping the filtering elements and the metal walls on the back surface side.

According to an embodiment, each pixel further comprises a microlens topping the filtering element on the back surface side.

According to an embodiment, each pixel further comprises a microlens topping the equalization layer on the back surface side.

According to an embodiment, the photosensitive areas are formed in a semiconductor layer and are separated from one another by insulating trenches.

According to an embodiment, the metal walls top, in vertical projection, the insulating trenches.

According to an embodiment, the height of the metal walls ranges from 0.5 to 1.5 μm.

According to an embodiment, the metal walls are made of a metal from the group comprising aluminum and tungsten.

According to an embodiment, an interconnection stack tops the photosensitive areas on the front surface side.

The foregoing and other objects, features, and advantages will be discussed in detail in the following non-limiting description of specific embodiments in connection with the accompanying drawings.

### BRIEF DESCRIPTION OF THE DRAWINGS

FIG. 1, previously described, is a cross-section view schematically and partially showing a backside image sensor;

FIG. 2 is a cross-section view schematically and partially showing an embodiment of a backside image sensor;

FIGS. 3A and 3B are simplified partial cross-section views illustrating steps of an example of a method for forming a sensor of the type described in relation with FIG. 2; and

FIGS. 4A to 4D are simplified partial cross-section views illustrating steps of another example of a method for forming a sensor of the type described in relation with FIG. 2.

### DETAILED DESCRIPTION

For clarity, the same elements have been designated with the same reference numerals in the different drawings and, further, as usual in the representation of integrated circuits, the various drawings are not to scale.

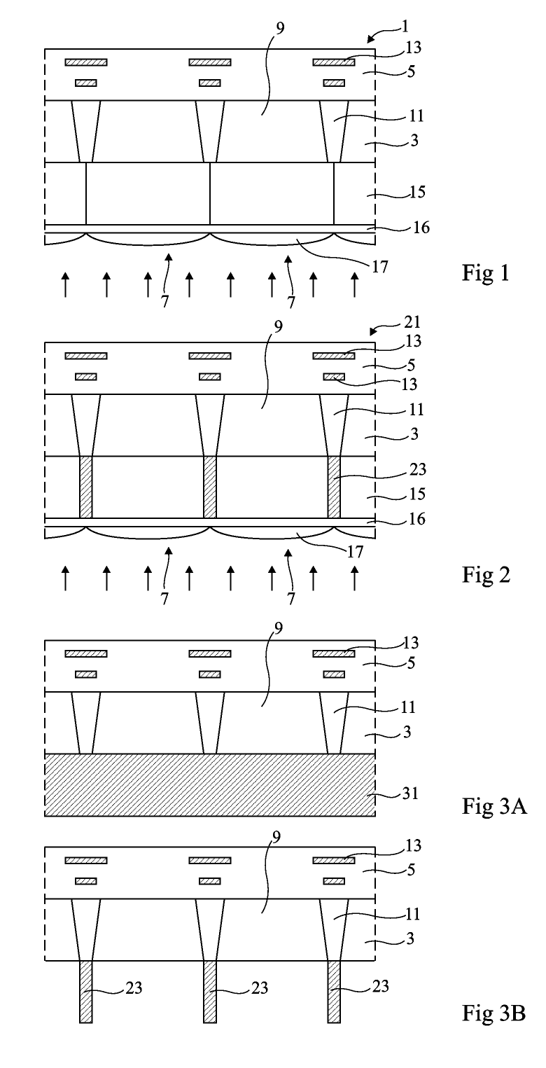

FIG. 2 shows a backside color image sensor 21. Sensor 21 has many similarities with sensor 1 of FIG. 1, and will not be described in detail hereafter. Only those elements which are useful to the understanding of the present invention will be discussed herein.

Sensor 21 comprises the same elements as sensor 1 of FIG. 1, that is, photosensitive areas 9 formed in a thinned substrate 3 and separated by insulating regions 11; an interconnection stack 5 topping the front surface of substrate 3; and color filtering elements 15, an equalization layer 16, and microlenses 17 on the back side of the substrate.

Sensor 21 further comprises, between filtering elements 15, vertical metal walls 23 separating filtering elements 15 from one another. “Vertical walls” is here used to designate walls orthogonal to the sensor plane. Walls 23 extend approximately along the entire height, for example, along at least 90% of the height of the filtering layer, and are preferably made of aluminum, of tungsten, or of any other metal capable of reflecting light.

Walls 23 enable to prevent any direct passing of light between adjacent filtering elements. When the path of a light ray encounters a wall 23, for example, if the ray has entered a filter 15 with too high an angle of incidence, this ray is reflected by wall 23. After reflection, the light reaches photosensitive area 9 corresponding to filter 15 through which the ray has entered the sensor. Thus, walls 23 enable to both avoid any crosstalk between adjacent filers, and increase the amount of photons received in the photosensitive areas, that is, the sensor sensitivity.

In the shown example, metal walls 23 have substantially the same width as insulating regions 11 separating photosensitive areas 9 from one another, that is, for example, a width approximately ranging from 30 to 60 nm, and are arranged in front of insulating layers 11. Such an arrangement ensures continuity between the optical isolation provided by walls 23, and the electric insulation provided by trenches 11.

In the shown example, walls 23 extend from the front surface of filtering layer 15 to the back surface of filtering layer 15. However, it may be provided for walls 23 to extend through equalization layer 16 to further improve the optical isolation between neighboring pixels.

In such a sensor, it is not useful to provide, for a peripheral pixel, an offset of filter 15 and of microlens 17 with respect to photosensitive area 9. Indeed, walls 23 are sufficient to ensure the convergence of the light received by the pixel towards the corresponding photosensitive area 9. This significantly simplifies the sensor design and manufacturing. A slight offset of microlenses 17 may however be provided to further optimize the sensor performance.

Further, the presence of metal walls 23 makes the sensor little sensitive to possible misalignments of microlenses 17, for example due to manufacturing process inaccuracies.

It should be noted that in an alternative embodiment, focusing microlenses may even be totally omitted. Walls 23 then extend all the way to the immediate neighborhood of the surface of exposure to light, and are thus sufficient to ensure the convergence of the light received by the pixel towards the corresponding photosensitive area 9. In this case, equalization layer 16 (FIG. 2) also has an antireflection function.

FIGS. 3A and 3B are simplified partial cross-section views illustrating steps of an example of a method for forming a backside image sensor of the type described in relation with FIG. 2.

During a step illustrated in FIG. 3A, before the forming of filtering elements 15 of the sensor, a metal layer 31, for example, made of aluminum, is deposited on the back side of thinned substrate 3. In this example, photosensitive areas 9 and insulating regions 11 have been previously formed in substrate 3. The thickness of layer 31 should be substantially equal to the height of metal walls 23 (FIG. 2) which are desired to be formed, for example, approximately ranging from 0.5 to 1.5 μm.

During a step illustrated in FIG. 3B, layer 31 is locally removed by etching. It is provided to remove metal 31 in front of photosensitive areas 9, to only keep a grid pattern of metal walls 23 orthogonal to the back side of substrate 3, in front of insulating regions 11. An etch stop layer (not shown) may be provided between metal layer 31 and the back side of thinned substrate 3.

During a subsequent step, not shown, filtering elements 15 are deposited between metal walls 23. Other elements of the sensor, for example, an equalization layer and microlenses, may then be formed according to current manufacturing steps.

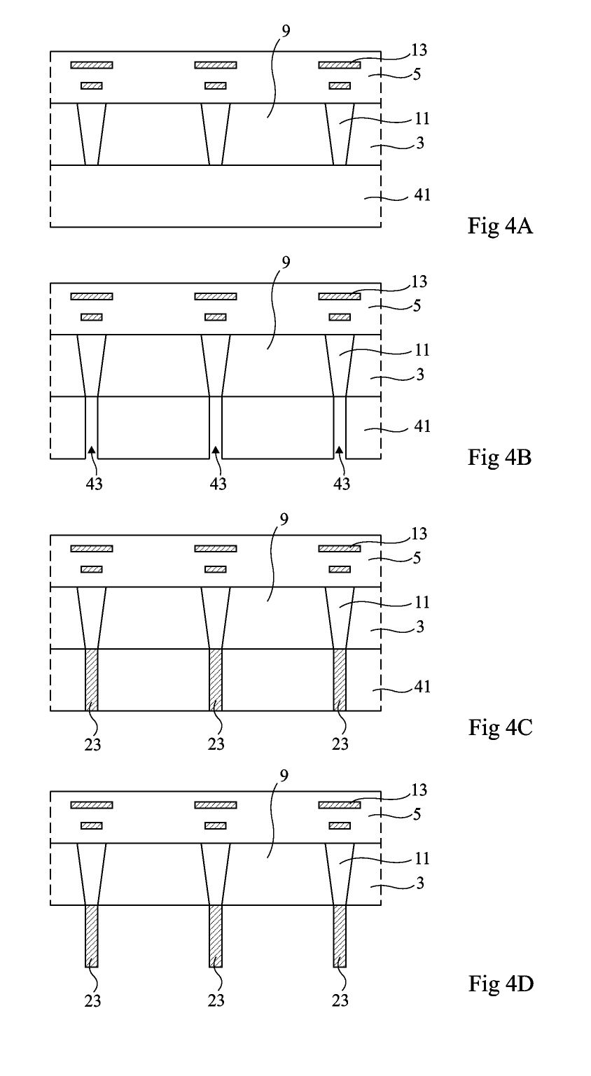

FIGS. 4A to 4D are simplified partial cross-section views illustrating steps of another example of a method for forming a backside image sensor of the type described in relation with FIG. 2.

During a step illustrated in FIG. 4A, before the forming of filtering elements 15 of the sensor, an insulating layer 41 is deposited on the back side of thinned substrate 3. In this example, photosensitive areas 9 and insulating regions 11 have been previously formed in substrate 3. Layer 41 for example is an oxide layer. Its thickness must be substantially equal to the height of metal walls 23 (FIG. 2) which are desired to be formed, for example approximately ranging from 0.5 to 1.5 μm.

During a step illustrated in FIG. 4B, trenches 43 are etched in layer 41, extending vertically across the entire thickness of layer 41. Trenches 43 delimit the metal walls 23 which are desired to be formed. They are, for example, formed in front of insulating regions 11 separating photosensitive regions 9 from one another.

During a step illustrated in FIG. 4C, trenches 43 are filled with metal, for example, tungsten, to form metal walls 23. An intermediary polishing step (not shown) may be provided to remove a possible excess metal from the surface of layer 41.

During a step illustrated in FIG. 4D, insulator 41 is removed, for example, by etching, to only keep the grid pattern formed by metal walls 23.

In a subsequent step, not shown, filtering elements 15 are formed between metal walls 23, and then possibly coated with an equalization layer and with microlenses.

It should be noted that an advantage of the provided sensor structure is that it enables to avoid, in the forming of filters 15, a possible color mixing in the interface areas between adjacent filters 15. The efficiency of color filters is thus improved.

Specific embodiments of the present invention have been described. Various alterations and modifications will occur to those skilled in the art. In particular, the present invention is not limited to sensors of the above-described type, wherein the photosensitive areas of adjacent pixels are separated by insulating trenches. It will be within the abilities of those skilled in the art to implement the desired operation whatever the structure of the photosensitive areas of the sensor. More generally, it will be within the abilities of those skilled in the art to implement the desired operation in any known structure of backside image sensor comprising filtering elements.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A backside image sensor comprising an assembly of pixels, each pixel comprising, in a vertical stack, a photosensitive area and a filtering element topping the photosensitive area on the back surface side, wherein at least two adjacent filtering elements of adjacent pixels are separated by a vertical metal wall extending over at least eighty percent of the height of the filtering elements or over a greater height.

2. The sensor of claim 1, further comprising an equalization layer topping the filtering elements and the metal walls on the back surface side.

3. The sensor of claim 1, wherein each pixel further comprises a microlens topping the filtering element on the back surface side.

4. The sensor of claim 2, wherein each pixel further comprises a microlens topping the equalization layer on the back surface side.

5. The sensor of claim 1, wherein the photosensitive areas are formed in a semiconductor layer and are separated from one another by insulating trenches.

6. The sensor of claim 5, wherein the metal walls top, in vertical projection, the insulating trenches.

7. The sensor of claim 1, wherein the height of the metal walls ranges between 0.5 and 1.5 μm.

8. The sensor of claim 1, wherein the metal walls are made of a metal from the group comprising aluminum and tungsten.

9. The sensor of claim 1, wherein an interconnection stack tops the photosensitive areas on the front surface side.
